(19) United States
(12) Patent Application Publication
(10) Pub. No.: US 2018/0151968 A1
(43) Pub. Date: May 31, 2018

(54) Electrical Connection Arrangement

(71) Applicant: Robert Bosch GmbH, Stuttgart (DE)

(72) Inventor: Uwe Liskow, Asperg (DE)

(21) Appl. No.: 15/571,642

(22) PCT Filed: Mar. 11, 2016
(86) PCT No.: PCT/EP2016/055349

§ 371 Date: Nov. 3, 2017

(30) Foreign Application Priority Data
May 6, 2015 (DE) 102015208413.2

(51) Int. Cl. H01R 12/59; H05K 5/00; H01R 12/62; H05K 3/28; H05K 3/36

(52) U.S. Cl. CPC H01R 12/592; H05K 5/0026; H05K 3/363; H05K 3/284; H01R 12/62

(57) ABSTRACT

An electrical connection arrangement includes an electronics module, a printed circuit board element, and a flexible conductor foil. The circuit board element includes a mounting area, an electronic circuit positioned on the mounting area, and a protective mass at least partially covering the electronic circuit to provide protection against environmental influences. The foil includes a base layer, a covering layer, and conductor tracks located therebetween. The electronics module includes a plurality of contact plates arranged next to each other, each having a respective contact end projecting away from a flank of the electronics module and electrically conductively connected to a respective conductor track of the foil. The protective mass forms a projection at the flank of the electronics module that supports the contact ends and at least one subregion of the foil. Such an arrangement is robust and compact.

### FIELD OF THE INVENTION

The invention relates to an electrical connecting arrangement which has an electronic module brought into contact with a flexible printed circuit foil. In particular, the invention relates to an electrical connecting arrangement having an electronic module for a transmission control device of a motor vehicle.

### PRIOR ART

In order to control transmissions, in particular automatic transmissions, in a motor vehicle, electronic modules are used, which generally have a transmission control unit with an electronic circuit (TCU), at least one plug connection for connection to a vehicle cable harness, electrical interfaces for activating actuators, and at least one sensor element.

In particular, the electronic circuit of the transmission control unit is frequently insert-molded and/or overmolded with a protective compound, for example a plastic compound made of thermosetting plastic or thermoplastic, for protection against environmental influences, for instance a transmission fluid washing around the transmission control unit and/or the electronic module.

Contact can be made with the electronic modules and/or the transmission control units for example by means of a circuit board element, a lead frame and/or a printed circuit foil.

DE 10 2010 039 187 A1 describes an electrical connecting arrangement having an electronic module which is brought into contact with a flexible flat cable, wherein the flat cable is able to be plugged in between a contact plate and a housing protrusion of the electronic module in a largely force-free manner.

### DISCLOSURE OF THE INVENTION

### Advantages of the Invention

Embodiments of the present invention can advantageously make it possible to provide a robust, flexible and virtually disruption-free electrical connecting arrangement, in particular for a transmission control device of a motor vehicle.

According to one aspect of the invention, an electrical connecting arrangement is proposed which has an electronic module with an electronic circuit arranged on a mounting surface of a circuit board element, and a flexible printed circuit foil with conductor tracks received between a base layer and a top layer. The mounting surface of the circuit board element and the electronic circuit are covered at least partially, preferably entirely, with a protective compound for protection against environmental influences. The electronic module has a plurality of contact plates, for example contact pins, arranged alongside one another, which each have a contact end projecting from a flank of the electronic module, wherein the contact ends of the contact plates are each connected in an electrically conductive manner to a conductor track of the printed circuit foil. The connecting arrangement according to the invention is characterized in particular in that a shoulder is formed by the protective compound at the flank of the electronic module, the contact ends of the contact plates and at least a subregion of the printed circuit foil being supported on said shoulder.

The contact ends and/or the subregion of the printed circuit foil can be supported for example fully on the shoulder. In this case, the shoulder can denote an edge, formed by the protective compound, of the electronic module. The shoulder can furthermore be formed on several flanks. It is also possible for the shoulder to encircle and/or for example annularly enclose the electronic module at an outer circumference of the electronic module.

The connecting arrangement and/or the electronic module can be used in particular in transmission control devices and be embodied so as to be washed around by a transmission fluid, wherein the protective compound can be embodied to protect the electronic circuit from the transmission fluid washing around the latter. The electronic circuit can for instance be part of a transmission control unit for a transmission control device.

By way of the connecting arrangement according to the invention, the electronic module can be brought into contact with the flexible printed circuit foil in a flat, compact and space-saving manner. Overall, a compact connecting arrangement for a transmission control device can be provided in this way. Furthermore, as a result of the contacting according to the invention, the contact ends of the contact plates and/or contact points at which the contact ends can be connected to the conductor tracks of the printed circuit foil can be protected comprehensively and reliably from short circuits which can be brought about for instance by conductive chips and/or depositions of the transmission fluid washing around the connecting arrangement.

Furthermore, on account of the flexibility of the printed circuit foil, which can be embodied for example in a limp manner and/or with a load-relieving corrugation in the longitudinal direction, thermomechanical changes in length, such as thermal expansion and/or bimetallic effects of the connecting arrangement, and displacements and/or vibrations of components of the connecting arrangement cannot act as shear forces, bending forces, tensile forces and/or compressive forces on the electrical contact points between the printed circuit foil and the contact plates. The contact points can have for example a soldered, welded and/or conductive-adhesive connection which can be accordingly robust, load-free and virtually disruption-free.

The connecting arrangement according to the invention and/or the bringing of the contact plates into contact with the printed circuit foil can allow automatable mounting of the connecting arrangement and easy variant management.

According to one embodiment of the invention, the contact ends of the contact plates rest on the shoulder. For example, the contact ends can rest fully on the shoulder and be supported. In this way, mechanical loads acting on the contact points can be reduced further.

According to one embodiment of the invention, the contact ends are each received at least partially in a depression formed in the shoulder. For example, the contact ends can be received in the depressions such that a contact surface of the contact ends can end flush with a surface of the shoulder.

According to one embodiment of the invention, the contact ends of the contact plates are each soldered, welded and/or adhesively bonded by means of conductive adhesive to a conductor track of the printed circuit foil.

According to one embodiment of the invention, a weld projection and/or a solder deposit is arranged at each of the contact ends of the contact plates. In this way, the conductor tracks and the contact ends can be connected for example by the closed base layer or top layer of the printed circuit foil, for example by laser welding, by means of hot bar soldering and/or by pressing on. The weld projection and/or the solder deposit can have approximately the thickness of the base layer and/or top layer of the printed circuit foil, such that contact can be made reliably with the conductor tracks. The solder deposit and/or the weld projection can have a thickness of around 10 to 100 μm.

According to one embodiment of the invention, in the subregion, supported on the shoulder, of the printed circuit foil, in each case at least one contact region of each conductor track is exposed by removal of the top layer or the base layer of the printed circuit foil and is connected in an electrically conductive manner to in each case one contact end of a contact plate. For example, recesses and/or slots can have been introduced into the top layer or base layer of the printed circuit foil in the contact regions, wherein the top layer or base layer can be present, i.e. not removed, between the conductor tracks.

According to one embodiment of the invention, in the subregion, supported on the shoulder, of the printed circuit foil, the top layer or the base layer of the printed circuit foil has been completely removed in order to bring the conductor tracks into contact with the contact plates. In other words, in the subregion, the printed circuit foil can have only the conductor tracks and the base layer or only the conductor tracks and the top layer.

According to one embodiment of the invention, the contact plates are each arranged with an end opposite the contact end on the mounting surface of the circuit board element, wherein the ends are fastened to the mounting surface with a crossbar that extends transversely to the direction of longitudinal extent of the contact plates and at least partially spans the contact plates. The ends, arranged on the mounting surface, of the contact plates can be embedded in the protective compound or be covered thereby. The crossbar can be produced from an electrically insulating material. With the aid of the crossbar, the contact plates can be stabilized further mechanically and robustness of the connecting arrangement can be enhanced.

According to one embodiment of the invention, a depression is formed in the shoulder between two directly adjacent contact ends, or a partition is formed by the shoulder between two directly adjacent contact ends. The depression and/or the partition can serve as chip protection such that conductive chips or depositions cannot settle on two adjacent contact ends and in the process short-circuit them.

According to one embodiment of the invention, a projection is arranged on the circuit board element, said projection engaging at least partially in a positioning recess introduced into the printed circuit foil in order to position the printed circuit foil. This can simplify in particular automated mounting and joining of the connecting arrangement.

According to one embodiment of the invention, the printed circuit foil is adhesively bonded in at least one subregion to the electronic module and/or to the shoulder. In this way, mechanical stability of the connecting arrangement can be enhanced further.

According to one embodiment of the invention, at contact points or in connecting regions between the contact ends of the contact plates and the printed circuit foil, the electrical connecting arrangement is covered at least partially by a polymer compound for protection against environmental influences, wherein the polymer compound contains an epoxy-resin-based, an acrylate-based, a polyurethane-based, a polyester-based, and/or a silicone-based material. As a result, the contact points can be additionally protected against environmental influences.

A further aspect of the invention can relate to a method for producing an electrical connecting arrangement as described above and below, and/or to an electronic module brought into contact with a printed circuit foil.

It should be noted that some of the possible features and advantages of the connecting arrangement are described herein with reference to different embodiments. A person skilled in the art will understand that the features can be combined, adapted or replaced in a suitable manner in order to arrive at further embodiments of the invention.

### BRIEF DESCRIPTION OF THE DRAWINGS

Embodiments of the invention are described in the following text with reference to the appended drawings, wherein neither the drawings nor the description should be interpreted as limiting the invention.

FIG. 1A shows a section through an electrical connecting arrangement according to one embodiment of the invention.

FIG. 1B shows a printed circuit foil of the connecting arrangement from FIG. 1A.

FIG. 2A shows a section through an electrical connecting arrangement according to one embodiment of the invention.

FIG. 2B shows a printed circuit foil of the connecting arrangement from FIG. 2A.

FIG. 3A shows a section through an electrical connecting arrangement according to one embodiment of the invention.

FIG. 3B shows a printed circuit foil of the connecting arrangement from FIG. 2A.

FIG. 3C shows a detail view of part of the connecting arrangement from FIG. 3A.

FIGS. 4A to 5B show a detailed side view of an electronic module for an electrical connecting arrangement according to embodiments of the invention.

The figures are merely schematic and not true to scale. Identical reference signs in the figures denote identical or functionally identical features.

### EMBODIMENTS OF THE INVENTION

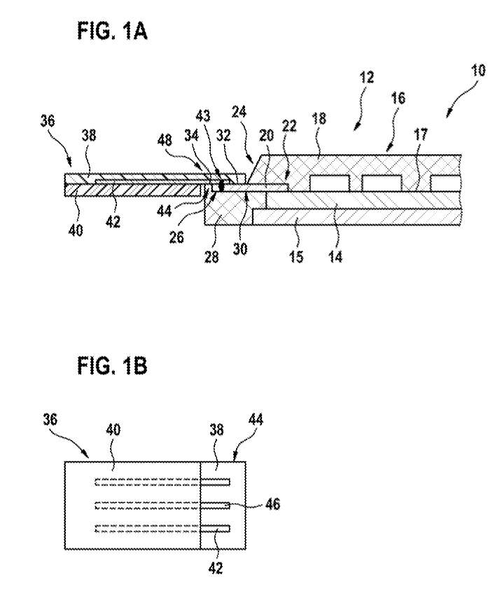

FIG. 1A shows a section through an electrical connecting arrangement 10 according to one embodiment of the invention. FIG. 1B shows a printed circuit foil 36 of the connecting arrangement in FIG. 1A.

The connecting arrangement 10 has an electronic module with a circuit board element 14, wherein an electronic circuit 16 is arranged on a mounting surface 17 of the circuit board element 14. The circuit board element 14 can be for example an HDI (“high-density interconnect”), a PCB (“printed circuit board”) element and/or some other circuit substrate such as ceramic (LTCC, HTCC). The electronic circuit 16 can have electronic components, for example housed and/or unhoused silicon components, sensor elements, plug connectors, SMD components (“surface mounted devices”) and/or other components. The electrical connecting arrangement 10 can also have a plurality of circuit board elements 14. The circuit board element 14 is arranged and/or fastened, with an opposite side or surface from the mounting surface 17, to a carrier element 15, for example a carrier plate made of metal and/or ceramic material.

In particular, the electronic circuit 16 can be part of a transmission control unit for a transmission control device of a motor vehicle. Furthermore, the electronic circuit 16 can be configured to be washed around by a transmission fluid. To this end, the electronic circuit 16 and the mounting surface 17 are covered at least partially, preferably entirely, with a protective compound 18 for protection against environmental influences and/or against transmission fluid. The protective compound 18 can be for instance polymer-based and/or contain thermosetting material, thermoplastic material, silicone-based material, polyurethane, acrylic-based material, polyester-based and/or acrylate-based material.

The electronic module 12 has a plurality of contact plates 20 for the electronic module 12 and/or the electronic circuit 16 to make electrical contact. The contact plates are fastened by one end 22 to the mounting surface 17 and electrically contacted, for example soldered, welded and or adhesively bonded by means of conductive adhesive. The contact plates 20 furthermore each have a contact end 26 projecting from a flank 24 of the electronic module 12, said contact end 26 being located opposite the end 22 in each case in the direction of longitudinal extent of the contact plates 20. At least one contact plate 20 can also be arranged on several flanks 24 of the electronic module 12. Contact plates 20 that are directly adjacent and arranged alongside one another can extend substantially parallel to one another and project with their contact ends 26 away from the respective flank 24 of the electronic module 12.

The electronic module 12 furthermore has, on the flank 24, a shoulder 28 formed by the protective compound 18, the contact ends 26 of the contact plates 20 each being supported on said shoulder 28. The shoulder 28 can in this case be arranged at a flank 24 or at a plurality of flanks 24 of the electronic module 12. It is also possible for the shoulder 28 to encircle and/or annularly enclose the electronic module 12 around an outer circumference, such that the carrier plate 15, the circuit board element 14 and/or the electronic circuit 16 can be protected by the shoulder 28 from lateral penetration of transmission fluid into the electronic module 12.

In the exemplary embodiment shown in FIG. 1A, the contact ends 26 of the contact plates 20 are each arranged and/or received in a depression 30 in the shoulder 28. The contact ends 26 can for instance be arranged in the depressions 30 such that a contact surface 32 of the contact ends 26 terminates in each case substantially flush with a surface 34 of the shoulder 28.

The electrical connecting arrangement 10 furthermore has a printed circuit foil 36 which has conductor tracks 42 received and/or arranged between a base layer 38 and a top layer 40. The top layer 40 can alternatively or additionally be a finish and/or have a finish. The printed circuit foil 36 is configured overall in a flexible and/or limp manner and can denote for instance a flexible circuit board and/or a flex foil.

The contact ends 26 of the contact plates 20 are each connected in an electrically conductive manner at a connecting point or contact point 43 to a conductor track 42 of the printed circuit foil 36. For example, the contact ends 26 are soldered, welded and or adhesively bonded by means of a conductive adhesive to the conductor tracks 42. For example, the contact ends and the conductor tracks 42 can be laser-welded through the top layer 40 and/or through the base layer 38 and/or brought into contact or connected by hot bar soldering and/or pressing on.

In order to ensure that the printed circuit foil 36 and the contact plates 20 can be brought into contact in a flat and compact manner and so as to be sealed off from transmission fluid, as can be seen in FIG. 1B, a subregion 44 of the top layer 40 of the printed circuit foil 36 is removed such that a contact region 46 of the conductor tracks 42 is exposed in the subregion 44 and can be connected to the contact ends 26. Alternatively, the printed circuit foil 36 can also be turned around and a subregion 44 of the base layer 38 can be removed. The subregion 44 can denote for instance an end of the printed circuit foil 36.

The printed circuit foil 38 is connected to the electronic module 12 such that the subregion 44 is supported at least partially on the shoulder 26 and/or rests on the shoulder 28 so that further contact can be made with the electronic module 12 in a flat and compact manner. Preferably, the subregion 44 rests fully on the shoulder 28 and the contact ends 26.

A connecting region 48 between the contact ends 26 of the contact plates 20 and the printed circuit foil 36 can furthermore be covered at least partially by a polymer compound for protection against environmental influences and/or transmission fluid. The polymer compound can contain an epoxy-resin-based, an acrylate-based, a polyester-based, a polyurethane-based and/or a silicone-based material. The connecting region 48 can in this case denote in particular an interface between the printed circuit foil 36 and the electronic module and comprise for example the subregion 44 of the printed circuit foil 36 and also the contact ends 26. The polymer compound can be crosslinked or cured for example by energy radiation (for example UV light) and/or heat. Furthermore, the subregion 44 of the printed circuit foil 36 can be adhesively bonded at least partially to the electronic module 12 and/or to the shoulder 28 such that no transmission fluid can pass as far as the contact ends 26 and/or the contact points 43.

For the positioning and automated joining of the electrical connecting arrangement 10, the circuit board element 14 can furthermore have a projection which can engage at least partially in a positioning recess introduced into the printed circuit foil 36. A plurality of projections and positioning recesses can also be provided.

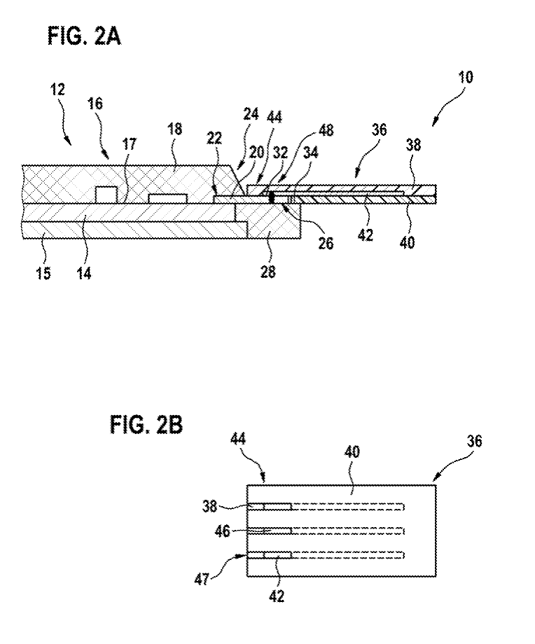

FIG. 2A shows a section through an electrical connecting arrangement 10 according to one embodiment of the invention. FIG. 2B shows a printed circuit foil 36 of the connecting arrangement 10 in FIG. 2A. Unless described otherwise, the connecting arrangement in FIG. 2A and the printed circuit foil 36 in FIG. 2B can have the same elements and features as the connecting arrangement 10 and printed circuit foil 36 described in previous figures.

In the exemplary embodiment shown in FIGS. 2A and 2B, the contact ends 26 of the contact plates 20 rest on the shoulder 28 or the surface 34 thereof, i.e. the contact ends 26 are not received in a depression 30 in the shoulder 28, as shown in FIG. 1A. In order nevertheless to be able to ensure that contact is made in a flat manner, the top layer 40 is not fully removed in the subregion 44 of the printed circuit foil 36, but rather slots or recesses 47 are introduced into the top layer 40 in the subregion 44, such that the contact regions 46 of the conductor tracks 42 are exposed and the contact ends 26 are each received and/or arranged in one of the recesses 47 in the top layer 40. Between the contact ends 26, the top layer 40 can thus rest on the surface 34 of the shoulder 28. Alternatively, the printed circuit foil 36 can also be turned around and the recesses 47 can be introduced into the base layer 38.

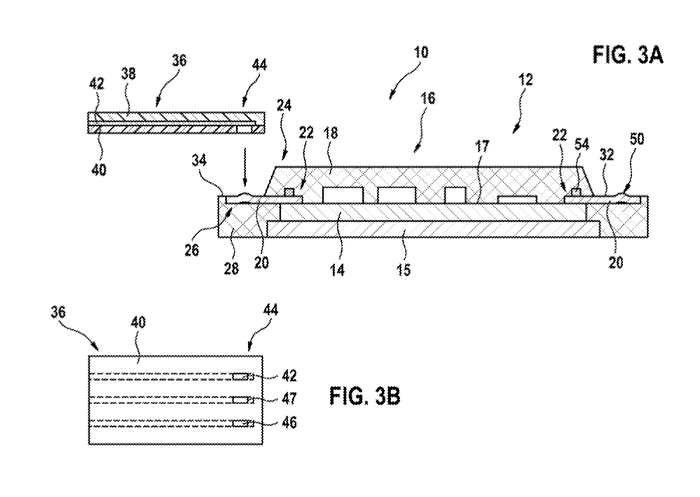

FIG. 3A shows a section through an electrical connecting arrangement 10 according to one embodiment of the invention. FIG. 3B shows a printed circuit foil 36 of the connecting arrangement 10 in FIG. 3A.

FIG. 3C shows a detail view of the connecting arrangement 10 in FIG. 3A. Unless described otherwise, the connecting arrangement 10 in FIG. 3A and the printed circuit foil 36 in FIG. 3B can have the same elements and features as the connecting arrangement 10 and printed circuit foil 36 described in previous figures.

In the exemplary embodiment shown in FIGS. 3A to 3C, a weld projection 50 and/or a solder deposit 52 is arranged at each of the contact ends 26 of the contact plates 20, the contact ends 26 being brought into contact with the conductor tracks 42 of the printed circuit foil 36 via said weld projection 50 and/or solder deposit 52. The contact ends 26 can either rest on the surface 34 of the shoulder 28 or be received in a depression 30 in the shoulder 28. Furthermore, in the subregion 44 of the printed circuit foil 36, only one contact region 46 of each conductor track 42 is exposed by removal of the top layer 40 or of the base layer 38; for example, a recess 47 can be introduced into the top layer 40 or the base layer 38 such that the contact regions 46 are exposed. The weld projections 50 and/or the solder deposits 52 can each be received in one of the recesses 47. The weld projections 52 can be formed for instance by reshaping the contact ends 26. The weld projections 50 and/or the solder deposits 52 can have a thickness which can correspond substantially to a thickness of the top layer 40 and/or of the base layer 38, such that a reliable electrical connection can be established. For example, the weld projections 50 and/or the solder deposits 52 can have a thickness of around 10 to 100 μm.

Furthermore, the contact plates 20, or the ends 22 of the contact plates 20, are fastened to the mounting surface 17 of the circuit board element 14 by an electrically insulating crossbar 54 that extends transversely to the direction of longitudinal extent of the contact plates 20 and spans the contact plates 20. The crossbar 54 can be produced for instance from plastics material and enhance mechanical stability of the connecting arrangement 10.

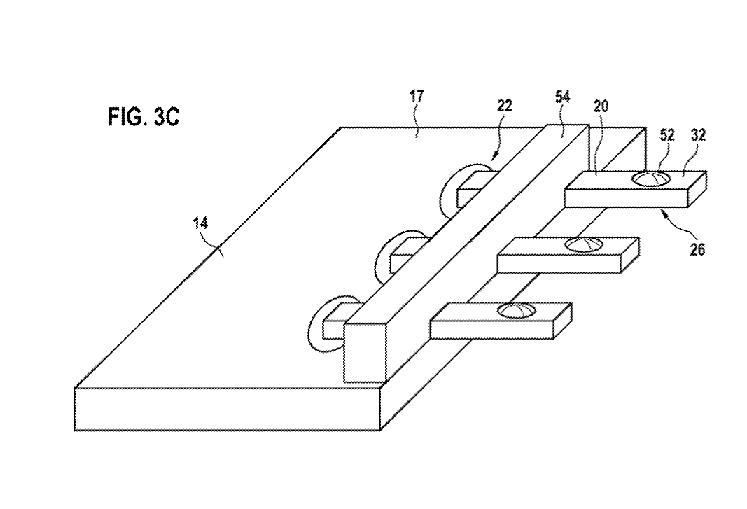

FIGS. 4A and 4B show a detailed side view of an electronic module 12 for an electrical connecting arrangement 10 according to one embodiment of the invention. Unless described otherwise, the electronic module 12 in FIGS. 4A and 4B can have the same elements and features as the electronic modules 12 described in previous figures.

For protection against short circuits, which can be brought about for instance by conductive chips or depositions of a transmission fluid washing around the electronic module 12, a depression 56 is formed in the shoulder 28, between in each case two directly adjacent contact ends 26, such that chips and or depositions can settle in the depressions 56 without establishing a conductive connection between two contact plates 20. The depressions 56 can thus act as chip protection for the connecting arrangement 10.

The depressions 56 can in this case each have a width which corresponds to a distance between two directly adjacent contact ends 20, as shown in FIG. 4A. Alternatively, the depressions 56 can have a width which is less than the distance between two directly adjacent contact ends 20, such that the contact ends laterally adjoin a material of the shoulder 28 and can be laterally in touching contact with the shoulder 28, as shown in FIG. 4B.

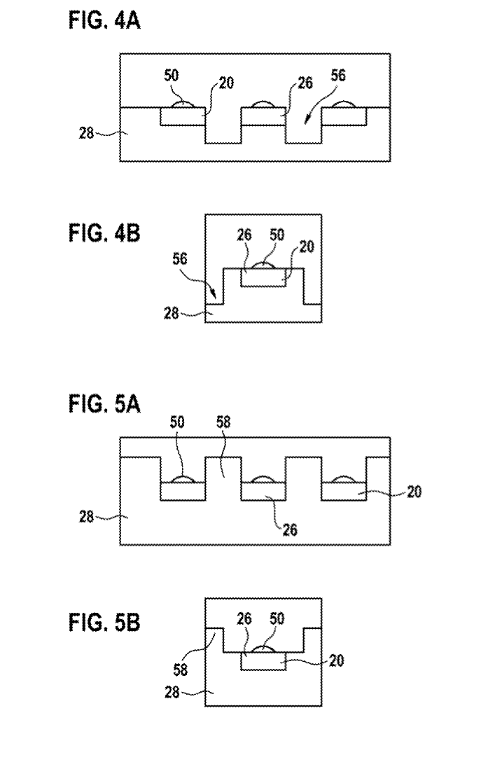

FIGS. 5A and 5B show a detailed side view of an electronic module 12 for an electrical connecting arrangement 10 according to one embodiment of the invention. Unless described otherwise, the electronic module 12 in FIGS. 5A and 5B can have the same elements and features as the electronic modules 12 described in previous figures.

Alternatively to the chip protection by depressions 56, described in FIGS. 4A and 4B, in the exemplary embodiments in FIGS. 5A and 5B, a partition 58 is formed by the shoulder 28 between in each case two directly adjacent contact ends 26, such that chips and depositions cannot short-circuit two adjacent contact ends 26.

In a similar manner to the depressions 56 in FIGS. 4A and 4B, the partitions 58 can each have a width which corresponds to a distance between two directly adjacent contact ends 20, as shown in FIG. 5A, or they can have a width which is less than the distance between two directly adjacent contact ends 20, as shown in FIG. 5B.

Finally, it should be noted that terms such as “having”, “comprising”, etc. do not rule out other elements or steps and terms such as “a” or “one” do not rule out a multiplicity. Reference signs in the claims should not be considered as limiting.

1. An electrical connecting arrangement comprising:
a circuit board element including a mounting surface;
a flexible printed circuit foil including a base layer, a top layer, and a plurality of conductor tracks located between the base layer and the top layer;
an electronic module including:
an electronic circuit positioned on the mounting surface of the circuit board element; and
a plurality of contact plates arranged alongside each other, each contact plate having a respective contact end that projects out from a flank of the electronic module, and that is electrically conductively connected to a corresponding conductor track of the plurality of conductor tracks; and
a protective compound that at least partially covers the mounting surface of the circuit board element and the electronic circuit, and that is configured to provide protection against environmental influences, the protective compound forming a shoulder at the flank of the electronic module, such that the shoulder supports the contact ends of the contact plates and at least a subregion of the flexible printed circuit foil.

2. The electrical connecting arrangement as claimed in claim 1, wherein at least one of:
the contact ends of the contact plates rest on the shoulder; and
the shoulder includes a plurality of depressions, and each contact end is received at least partially in a respective one of the depressions.

3. The electrical connecting arrangement as claimed in claim 1, wherein each of the contact ends of the contact plates is at least one of soldered, welded and adhesively bonded via conductive adhesive to the corresponding conductor track of the flexible printed circuit foil.

4. The electrical connecting arrangement as claimed in claim 1, further comprising:
at least one of a respective weld projection and a respective solder deposit positioned at each of the contact ends of the contact plates.

5. The electrical connecting arrangement as claimed in claim 1, wherein
one of the top layer and the base layer of the flexible printed circuit foil is arranged so as to expose a contact region of each conductor track that is located in the subregion supported on the shoulder and
each of the exposed contact regions is electrically conductively connected to the contact end of a corresponding contact plate.

6. The electrical connecting arrangement as claimed in claim 1, wherein one of the top layer and the base layer does not extend into the subregion, supported on the shoulder, of the printed circuit foil, to enable contact between the plurality of conductor tracks and the contact plates.

7. The electrical connecting arrangement as claimed in claim 1, further comprising:
a crossbar that extends transversely to a direction of longitudinal extent of the contact plates and that spans the contact plates;
wherein:
the contact plates are each arranged such that a distal end of each contact plate, opposite the contact end, is positioned on the mounting surface of the circuit board element, and
the crossbar fastens the distal ends to the mounting surface.

8. The electrical connecting arrangement as claimed in claim 1, wherein (i) the shoulder includes a depression located between two directly adjacent contact ends, or (ii) the shoulder includes a partition between two directly adjacent contact ends.

9. The electrical connecting arrangement as claimed in claim 1, wherein at least one of:
(i) the circuit board element further includes a projection, the flexible printed circuit foil further includes a positioning recess, and the projection at least partially engages the positioning recess so as to position the flexible printed circuit foil; and
(ii) the subregion of the flexible printed circuit foil is at least partially adhesively bonded to at least one of the electronic module and the shoulder.

10. The electrical connecting arrangement as claimed in claim 1, further comprising:
a polymer compound that at least partially covers the electrical connecting arrangement in a connecting region between the contact ends of the contact plates and the printed circuit foil, the polymer compound configured to provide protection against environmental influences,
wherein the polymer compound includes a material based on at least one of an epoxy resin, an acrylate, a polyurethane, a polyester, and a silicone.
